(19) United States
(12) Patent Application Publication
(10) Pub. No.: US 2026/0322106 A1
(43) Pub. Date: Oct. 15, 2026

(54) METHODS AND SYSTEMS FOR PRECHARGE SHORT CIRCUIT DETECTION AND PROTECTION FOR A BATTERY PACK

(71) Applicant: A123 Systems LLC, Novi, MI (US)

(72) Inventors: Anudeep Peteti, Farmington Hills, MI (US); Aman Jain, Farmington Hills, MI (US); Miguel Jose Tovar, Novi, MI (US)

(21) Appl. No.: 19/644,983

(22) Filed: Apr. 10, 2026

Related U.S. Application Data
(60) Provisional application No. 63/787,629, filed on Apr. 11, 2025.
(60) Provisional application No. 63/823,632, filed on Jun. 13, 2025.

(51) Int. Cl. H02H 7/18; G01K 3/00; G01R 31/3842; G01R 31/52; H02J 7/62; H02J 7/80; H02J 7/90

(52) U.S. Cl. CPC H02H 7/18; G01K 3/005; G01R 31/3842; G01R 31/52; H02J 7/62; H02J 7/80; H02J 7/933; H02J 7/975

(57) ABSTRACT

Systems and methods are provided for a precharge circuit of a battery pack. The method includes closing a precharge relay of the precharge circuit, storing a precharge time in non-volatile memory of a controller of the battery pack if an absolute value of a difference between a stack voltage and a terminal voltage is less than a precharge threshold and outputting an error message if the difference is not less than the precharge threshold and if a value of a precharge check accumulator is greater than energy threshold. After, the method includes opening the precharge relay and if the precharge time is stored closing the precharge relay and precharging and monitoring for short circuit and/or overcurrent conditions using the stored precharge time.

### CROSS REFERENCE TO RELATED APPLICATIONS

The present application claim priority to U.S. Provisional Application No. 63/823,632 entitled “METHODS AND SYSTEMS FOR PRECHARGE SHORT CIRCUIT DETECTION AND PROTECTION FOR A BATTERY PACK” and filed on Jun. 13, 2025. The present application also claims priority to U.S. Provisional Application No. 63/787,629 entitled “BATTERY PACK OVERCURRENT PROTECTION” and filed on Apr. 11, 2025. The entire contents of the above applications are hereby incorporated by reference for all purposes.

### FIELD

The present description relates generally to a system and methods for protecting battery components from overcurrent and short circuit during precharging.

### BACKGROUND AND SUMMARY

A precharge circuit is included in many battery packs. The precharge circuit is configured to equalize voltage differences between the battery pack and a device coupled to the battery cells. In this way the battery pack may be connected and disconnected from circuits with different voltages without arcing and degradation to electrical components of the battery pack during power-up or shut down. Conventionally a battery pack may determine that precharge was successful and close a main relay to the device, or the system may determine that the precharge was not successful, wait a time period and then retry precharging. This may help to avoid overheating between subsequent precharge attempts, but may not determine the underlying cause of the unsuccessful precharge, resulting in degradation of components. Further, the wait time may result in delays in operating the device that are frustrating to a user. Additionally, conventional determination that precharge was not successful is based on a maximum current limit and does not account for energy accumulation or dissipation over time, either during precharging or between retries.

The inventors herein have identified the above problems and have determined solutions to at least partially solve them. In one example, a method for a precharge circuit of a battery pack, includes: closing a precharge relay of the precharge circuit; storing a precharge time in non-volatile memory of a controller of the battery pack if an absolute value of a difference between a stack voltage and terminal voltage is less than a precharge threshold and outputting an error message if the difference is not less than the precharge threshold and a value of a precharge check accumulator is greater than an energy threshold, opening the precharge relay; and if the precharge time is stored, closing the precharge relay and precharging and monitoring for short circuit and/or overcurrent conditions using the stored precharge time. In this way, the algorithm may adaptively learn precharge constraints based on environment of the battery pack and automatically adapt functionality to fit the environment.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 shows a block diagram of a system including a battery pack including precharge short circuit and overcurrent protection.

FIG. 2 shows a diagram of the battery pack including a precharge circuit and precharge short circuit and overcurrent protection.

FIG. 3 shows a flowchart of a method for determining a status of the precharge circuit for precharge short circuit and overcurrent protection.

FIG. 4 shows a flowchart of a first example of a method for precharge short circuit and overcurrent protection.

FIG. 5 shows a flow chart of second example of a method for precharge short circuit and overcurrent protection.

FIG. 6 shows a diagram of timing of precharging.

### DETAILED DESCRIPTION

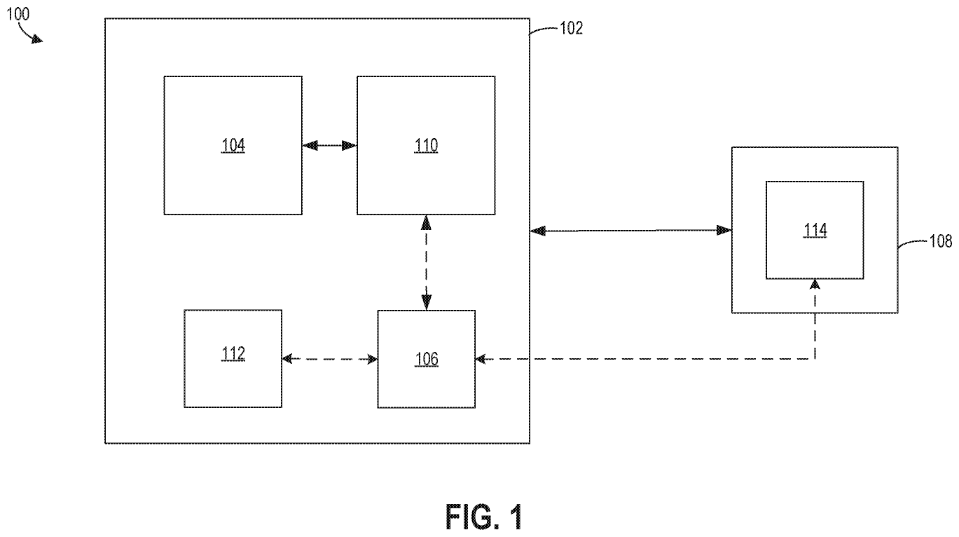

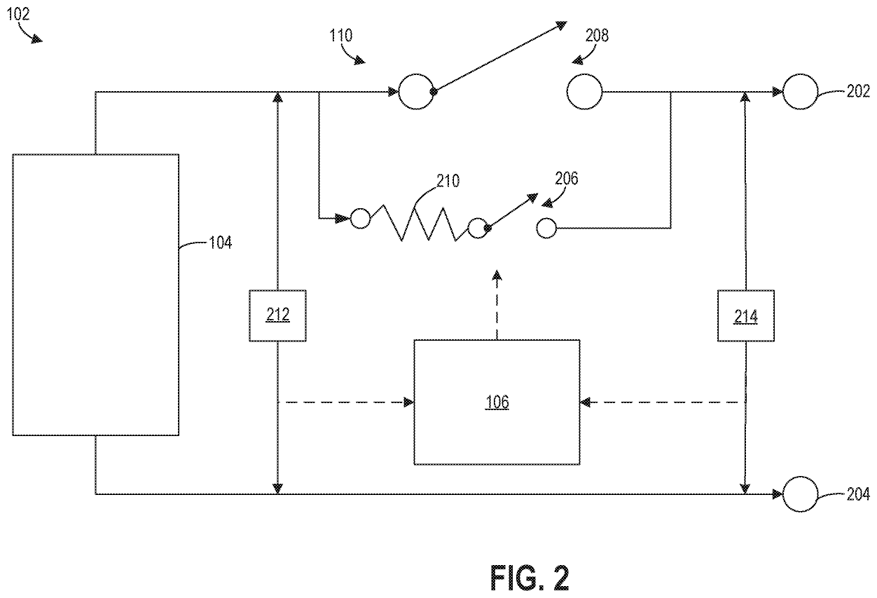

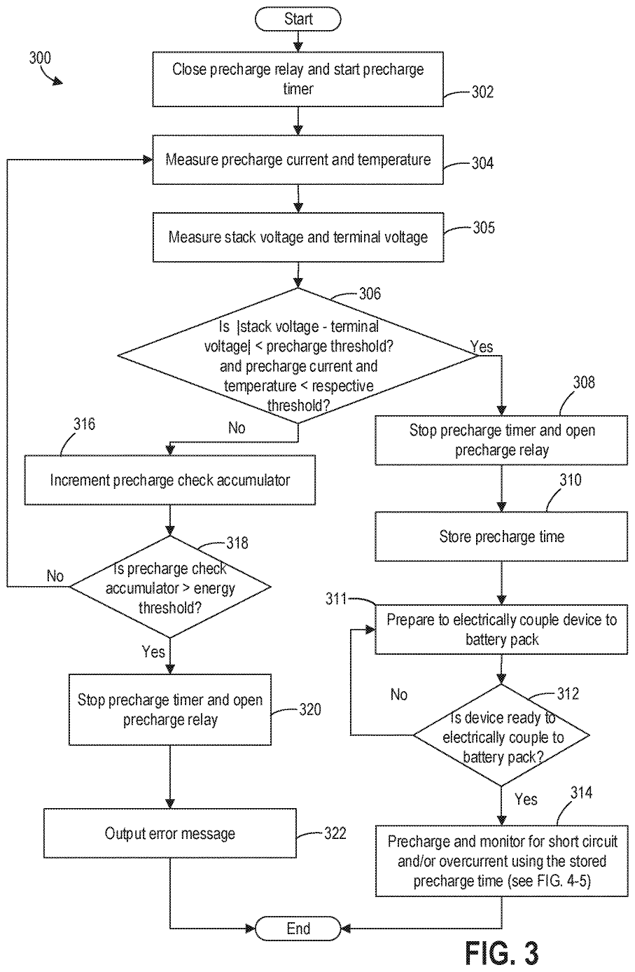

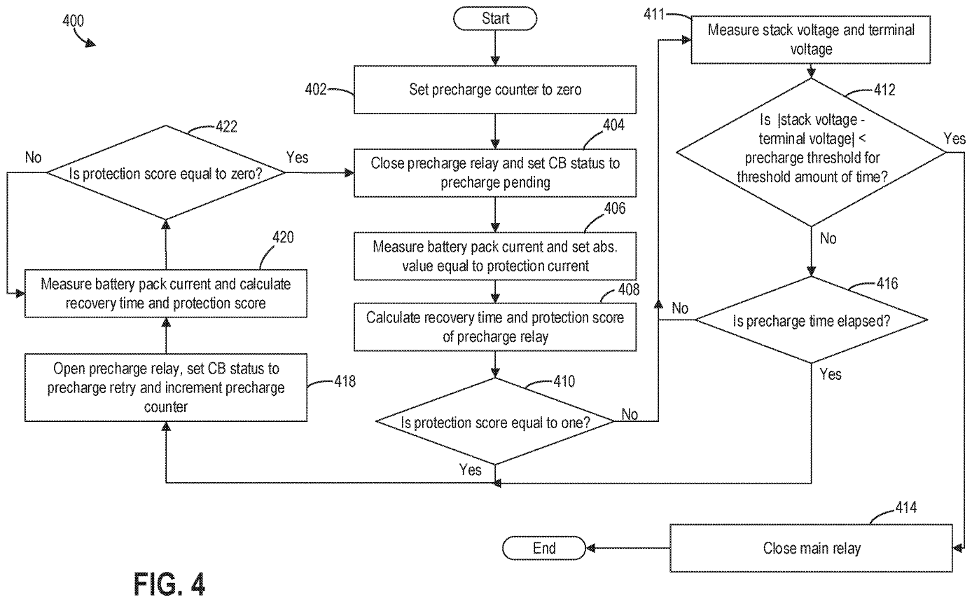

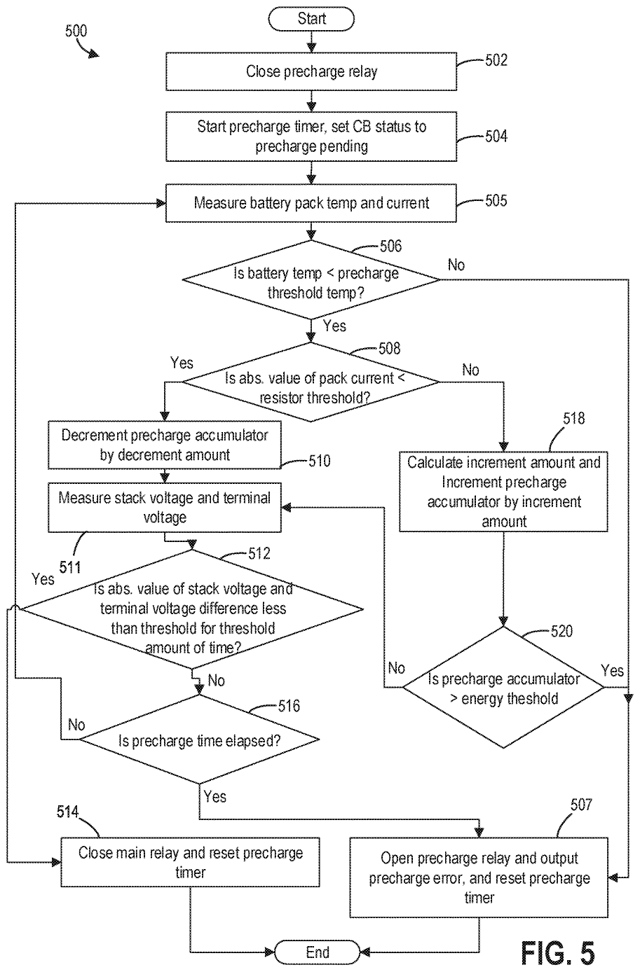

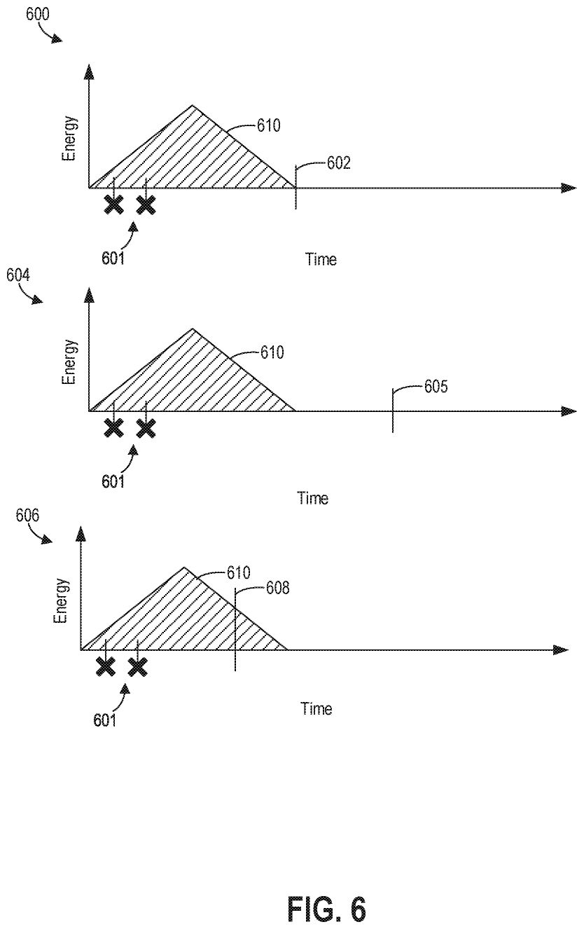

The following description relates to systems and methods for overcurrent and short circuit protection for a precharge circuit. A block diagram of a system including a battery pack coupled to a device is shown in FIG. 1. The battery pack may include a precharge circuit configured to slowly equalize voltages of the device and the battery pack when they are electrically coupled to each other in order to slow degradation of both the battery pack and the device. A non-limiting example of a precharge circuit of the battery pack is shown in FIG. 2. The battery pack may include a controller storing instructions to check a status of the precharge circuit and determine an expected precharging time before starting precharge, an example of which is shown in FIG. 3. The controller may include further instructions to determine if a short circuit and/or overcurrent event is occurring during precharging and to automatically open and close relays of the precharge circuit in response, examples of which are shown in FIGS. 4 and 5. The methods may dynamically control a timing of re-try in the event that a precharge attempt fails. Diagrams of FIG. 6 compare re-try timing of the disclosed methods to conventional static re-try timing.

Turning now to FIG. 1, a system 100 is shown including a battery pack 102 electrically coupled to a device 108. Device 108 may be a load and/or source configured to receive energy from or supply energy to battery pack 102. In one example, when device 108 is the load, the load may be included in a vehicle. For example, the load may be an electric machine of an electric or hybrid vehicle functioning as a motor. Additionally or alternatively the load may be a starter of an internal combustion engine and/or the load may be electrical accessories of the vehicle. In some examples device 108 may be a DC-DC converter. The DC-DC converter may be positioned to couple a high voltage (HV) system and low voltage system (LV). In an alternate example, when device 108 is the source, the source may be included in a charging system configured to flow current to battery pack 102. For example, the source may be a charging station for an electric vehicle and/or the source may be the electric machine of the vehicle functioning as a generator. In further examples, the battery pack 102 may be the battery pack may be configured to store energy generated by a renewable energy source. Additionally or alternatively, the battery pack 102 may be a backup energy source, such as for a business or for a home energy system and device 108 may be an inverter.

Battery pack 102 may include a plurality of battery cells 104 and a precharge circuit 110 electrically coupled to the plurality of battery cells. Battery pack 102 may further include a battery controller 106. Battery controller 106 may be communicatively coupled to precharge circuit 110. Battery pack 102 may further include sensors 112. Sensors 112 may be communicatively coupled to battery controller 106. Sensors 112 may include, but are not limited to, voltage sensors, current sensors, and temperature sensors. Battery controller 106 may include non-volatile memory storing instructions to operate precharge circuit 110 based on input from sensors 112. Battery controller 106 may be communicatively coupled to a device controller 114. In one example, device controller 114 may be configured to receive error messages output by battery controller 106 and operate the device accordingly. Battery controller 106 may be configured to selectively electrically couple and decouple device 108 from battery pack 102, for example by opening and closing a relay positioned selectively interrupt the electrical coupling between battery pack 102 and device 108. For example, the relay and battery controller 114 may both be positioned within the battery pack 102. Alternatively, the relay may be opened and closed by device controller 114. For example, the relay control may be external to the battery pack 102.

Turning now to FIG. 2 a simplified non-limiting example circuit diagram of battery pack 102 is shown. The plurality of battery cells 104 may be electrically coupled to a first terminal 202 and a second terminal 204. For example, first terminal 202 may be a positive terminal and second terminal 204 may be a negative terminal. First terminal 202 and second terminal 204 may be the points where battery pack 102 couples to a device such as device 108 shown in FIG. 1.

Battery pack 102 may also include precharge circuit 110 positioned between the plurality of battery cells 104 and first terminal 202 with respect to the flow of electricity. Precharge circuit 110 may include a precharge relay 206 and a main relay 208. One or both of precharge relay 206 and main relay 208 may be field effect transistors (FETs). Precharge relay 206 may be positioned in parallel with main relay 208. Precharge circuit 110 may further include a resistor 210 positioned between the plurality of battery cells and precharge relay 206 with respect to the flow of electricity. Precharge circuit 110 may be communicatively coupled to battery controller 106 and may receive instructions from battery controller 106 to independently open and close precharge relay 206 and main relay 208.

Battery pack 102 may further include a stack voltage sensor 212 and a terminal voltage sensor 214. Stack voltage sensor 212 may be electrically coupled to battery pack 102 between the plurality of battery cells 104 and precharge circuit 110 with respect to the flow of electricity. In this way, stack voltage sensor 212 may be configured to measure a voltage across the plurality of battery cells 104 (e.g., the battery stack). Terminal voltage sensor 214 may be electrically coupled to battery pack 102 between the terminals (e.g., first terminal 202 and second terminal 204) and precharge circuit 110 with respect to the flow of electricity. In this way, terminal voltage sensor 214 may be configured to measure a voltage across the first terminal 202 and second terminal 204. Both stack voltage sensor 212 and terminal voltage sensor 214 may be communicatively coupled to battery controller 106.

When a battery pack, such as battery pack 102 is electrically coupled to a device, a controller, such as battery controller 106 may command a precharge relay, such as precharge relay 206, to close for a duration before closing a main relay, such as main relay 208. Closing the precharge relay first may force current flowing between the device and the plurality of battery cells to first pass through a resistor (e.g., resistor 210). In this way, the current is decreased and an increase in voltage caused by electrically coupling to the device is slowed to help prevent arcing and premature degradation of the battery pack and device electronic components. Once voltages at the plurality of battery cells and terminals are similar the main relay may be closed to allow the higher current flow between the battery pack and the device. In some examples, a short circuit and/or overcharge condition may cause closing the precharge relay to not result in the similar voltages. Conventionally, a battery pack may determine the voltages are not similar and may simply retry closing the precharge relay if the expected result does not occur, without considering the energy accumulated in the precharge circuit. The methods described herein adaptively learn a precharging time of a battery pack and use the precharging time in addition to sensors of the battery pack to determine if short circuit and/or overcharge conditions are occurring based on energy accumulated and dissipated. The method further provides for retrying precharging within a time for allowing the accumulated energy to dissipate but without waiting overly long.

Turning now to FIG. 3, a flowchart of an example of a method 300 for a precharge bus check and precharging is shown. The instructions of method 300 and other methods disclosed herein may be stored in non-volatile memory on a controller of a battery pack, such as battery controller 106 of battery pack 102 and is herein referred to as a controller. The battery pack may include a precharge circuit, such a precharge circuit 110 of FIGS. 1-2 communicatively coupled to the controller. The steps of the methods described herein may be performed automatically by a processor of the controller in response to the battery pack being coupled to a device or receiving a request from a user or from the device to couple to the device. Herein, “automatically” refers to steps performed by the controller without additional input by a user. At the start of method 300, both a precharge relay and main relay of the precharge circuit may be open. Method 300 may be executed automatically in response to a request to electrically coupling the battery pack to a device.

At 302, method 300 includes closing a precharge relay, such as precharge relay 206 of FIG. 2, and starting a precharge timer. The precharge timer may be stored in the non-volatile memory of the controller. Closing the precharge relay may allow current to flow from a plurality of battery cells (e.g., plurality of battery cells 104) through a resistor and to the terminals of the battery pack in precharge testing configuration. In the precharge testing configuration, the battery pack may not be electrically coupled to the device by closing the precharge relay. At 302, the battery pack may be plugged into or otherwise physically coupled to the device but a relay or similar component may prevent electricity from flowing to the device from the battery pack. In this way, closing the precharge relay at 302 may be for a precharge bus check and may occur before precharging when the device is electrically coupled.

At 304, method 300 includes measuring the precharge current and temperature. The precharge current and temperature may be measured by respective sensors of the battery pack communicatively coupled to the controller. The measured precharge current may include the current flowing from the plurality of battery cells through the precharge relay to the terminals.

At 305, method 300 includes measuring a stack voltage and a terminal voltage of the battery pack. The stack voltage may be measured by a stack voltage sensor, such as stack voltage sensor 212 of FIG. 2 and the terminal voltage may be measured by a terminal voltage sensor, such as terminal voltage sensor 214 of FIG. 2.

At 306, method 300 determines if the absolute value of the difference between the stack voltage and the terminal voltage is less than a precharge threshold, and the precharge current is less than a precharge current threshold, and the temperature is less than a temperature threshold. In this way, the method 300 may determine if the voltage between the terminals of the battery pack is equalized to the voltage of the plurality of battery cells. The precharge threshold may be a voltage below which is indicative of successful precharge and equalization of the battery voltage and terminal voltage. As one example, the precharge threshold may be 400 mV. The precharge current threshold may be a current threshold above which the current may prematurely degrade the precharge circuit and other battery pack components. The temperature threshold may be a temperature above which the heat may prematurely degrade the precharge circuit and other battery pack components.

If method 300 determines than the absolute value of the voltage difference is less than the precharge threshold, and the precharge current and temperature are less than the respective thresholds (YES), method 300 proceeds to 308 and includes stopping the precharge timer and opening the precharge relay. In some examples, the main relay may close before the precharge relay is opened. At 310, method 300 includes storing a precharge time. Storing the precharge time may include saving the precharge time in non-volatile memory of the controller. The precharge time may be an elapsed time between starting the precharge timer at 302 and stopping the precharge timer at 308. In this way, the controller may learn an expected time for precharging (e.g., equalization of voltages to within the precharge threshold) to occur.

At 311, method 300 includes preparing to electrically couple the battery pack to the device. Preparing may include enabling the battery pack to electrically couple to the device. For example, the controller of the battery pack may be communicatively coupled to a controller of the device and may prepare for electrically coupling.

At 312, method 300 determines if the device is ready to electrically couple to the battery pack. At this time, both the precharge relay and main relay of the precharge circuit may be open, no current is flowing from the battery pack to the device, and the device will be electrically coupled to the battery pack if the precharge relay or main relay closes. The controller may check to see if the command to close the relay to couple the device to the battery pack is still true. For example, there may be a feedback loop for the command to close the relay. As one example, the feedback loop may be a timed feedback loop.

If method 300 determines that the device is not ready to electrically couple to the battery pack (NO), method 300 returns to 312 and continues to wait for the device to be ready to be electrically coupled to the battery pack. If method 300 determines that the device is ready to electrically couple to the battery pack (YES), method 300 proceeds to 314 and includes precharging while monitoring for short circuit and/or overcurrent conditions. Precharging may include closing the precharge relay of the precharge circuit and waiting to equalize voltages between the plurality of battery cells and the terminals of the battery pack. Examples of methods for performing step 314 are described further below with respect to FIGS. 4 and 5. Method 300 ends.

If, at 306, method 300 determines that the absolute value of the difference between the stack voltage and terminal voltage is not less than the precharge threshold, or the precharge current and temperature are not less than the respective thresholds (NO), method 300 proceeds to 316 and includes incrementing a precharge check accumulator. The precharge check accumulator may be a variable stored in the non-volatile memory of the controller used to track energy accumulated by the precharge relay during precharging. Incrementing the precharge accumulator may include increasing a value of the stored variable by an amount. The amount by which the precharge check accumulator is incremented may be determined by equation 1 below.

Increment=I²Rt (1)

I is a measured current of the battery pack in amps, R is the resistance of the precharge resistor, t is a time constant equivalent to the time of one current measurement loop of the battery pack. As one example R may be 1.25 ohms and t may be 0.01 s. The increment may be added to a previous value of the precharge check accumulator stored on the controller.

At 318, method 300 determines if the precharge check accumulator is greater than an energy threshold. The controller may compare the stored precharge check accumulator amount to an energy threshold value, also stored in the non-volatile memory of the controller. The energy threshold may be a total heat energy which may be accumulated by the resistor and precharge relay before degradation is likely occur. In this way, the threshold energy depends on a current withstood by the resistor over time. As one example the energy threshold may be 75 joules. If at 318, method 300 determines the precharge check accumulator is not greater than the energy threshold value (NO), method 300 returns to 305 and again measures the stack voltage and terminal voltage and returns to 304 to re-measure precharge current and temperatures before proceeding to 305 to re-measure stack voltage and terminal voltage and on to 306 to again determine if the voltage difference is less than the precharge threshold.

If at 318, method 300 determines that the precharge check accumulator is greater than the energy threshold (YES), method 300 proceeds to 320 and includes stopping the precharge timer. At 320, method 300 does not include storing the precharge time because both the voltage difference did not become lower than the precharge threshold and the precharge check accumulator reached above the energy threshold. In this way, the method determines that the precharge relay was not successfully closed and that the precharge circuit is on a bus not configured for the precharge circuit. At 322, method 300 outputs an error message. Outputting the error message may include indicating an error at the battery pack. For example, the battery pack may be configured to emit a light or sound which indicates to the user that the precharge circuit is not on an appropriate bus. As another example, outputting the error may include outputting the error to a controller of the device communicatively coupled to the battery pack. The device may convey to the user that the precharge circuit is not an appropriate bus, for example, by light or sound or via a display. Method 300 ends.

Turning now to FIG. 4, an example of a method 400 for precharging using a precharging circuit while monitoring and preventing short circuit and overcurrent conditions is shown. Method 400 may occur after a precharge time is successfully determined and stored at the controller and the device is ready to electrically coupled to the battery pack, as described above with respect to FIG. 3.

At 402, method 400 includes setting a precharge counter to zero. The precharge counter may be a variable stored in non-volatile memory of the controller to track a number of precharging attempts. Setting the precharge counter to zero may include assigning a value of zero to the precharge counter variable. At 404, method 400 includes closing the precharge relay and setting the circuit breaker status to precharge pending. Closing the precharge relay may electrically couple the battery pack to the device. Because the main relay is open at 404, current may be forced to flow through the precharge relay and the resistor (e.g., resistor 210). The circuit breaker status may be a status stored in non-volatile memory of the controller. The circuit breaker status may refer to a status of the main relay. In some examples the device controller may read the circuit breaker status from the controller of the battery pack.

At 406, method 400 includes measuring a battery pack current and setting an absolute value of the battery pack current equal to a protection current. Measuring the battery pack current may include determining a magnitude of current flowing through the battery pack from measurements made by a current sensor communicatively coupled to the controller. The protection current may be a value saved in non-volatile memory of the controller and may be used in calculation of recovery time and a protection score as described further below.

At 408, method 400 includes calculating a recovery time and protection score of the precharge relay. For example, the recovery time and protection score may be calculated for an FET comprising the precharge relay. The recovery time and protection score may quantify an amount of heat accumulated and an amount of heat dissipated by the precharge relay at the protection current. The recovery time may be calculated using equation 2 below.

$$Recovery Time = \frac{Relay Max Power}{{CurrentLimit}^{2}} 0.5 \qquad ( 2 )$$

RelayMaxPower is the maximum rated power of the relay at the measured protection current, CurrentLimit is a nominal operation current limit for the relay, and 0.5 is an empirically determined scaling constant. RelayMaxPower may be determined from a lookup table stored on non-volatile memory of the controller. The lookup table may specific to the precharge relay and may be used to relate the measured current to a maximum power withstood by the precharge relay at that current.

The protection score may be calculated based on the protection current and the recovery time using equation 3 below.

$$Protection Score = Min [ Max [ ( X n - 1 + \frac{{ProtectionCurrent}^{2} * Δ T}{Relay Max Power * 0.5} - \frac{Δ T}{RecoveryTime} ) , 0 ] , 1 ] \qquad ( 3 )$$

ProtectionCurrent is the protection current set at step 406, RecoveryTime is determined according to equation 2 above, and ΔT is a time interval for the measurement loop. ΔT may be a sample rate of the controller and may be dependent on the controller. As one example ΔT, may be 0.01 s. Xn is the protection score determined for the precharge relay in a previous loop of the method. In this way a first protection score may be used to determine a second protection score, the second protection score replacing the first protection score on a second iteration of the calculation when there is retry at precharging as described further below. As shown in equation 3, if a ratio of the effective power to the maximum rated power is greater than the ratio of ΔT to the recovery time, than the protection score is increased and if it is less than the ratio of ΔT to the recovery time than the protection score is decreased. The Min and Max function of the score may either increase the score to zero or decrease the score to one if the number goes outside of the zero to one range. Zero and one are examples of minimum and maximum values. In alternate examples, equation 3 may include other scaling factors in which case the Min and Max functions may be set to be numbers other than zero and one respectively. In this way, the protection score is dynamically adjusted based on the measured current and physical properties of the precharge relay.

At 410, method 400 determines if the protection score calculated at 408 is equal to one. If the protection score is not equal to one (NO), this may indicate that the precharge circuit is not in a short circuit and/or overcurrent condition and method 400 proceeds to 411 and measures a stack voltage and a terminal voltage. A stack voltage sensor may be used to measure the stack voltage and terminal voltage sensor may be used to measure the terminal voltage, similar to step 305 of method 300.

At 412, method 400 determines if an absolute value of a difference of the stack voltage and terminal voltage is less than a precharge threshold for a threshold amount of time. The stack voltage may be determined by a stack voltage sensor and the terminal voltage may be determined by a terminal voltage sensor. In this way step 412 is similar to step 306 of method 300 and is determining if the precharge relay has successfully slowly equalized the voltages at the plurality battery cells and the terminals. As one example, the precharge threshold may be 2V. The threshold amount of time may be 40 ms.

If at 412, method 400 determines that the absolute value of the difference between the stack voltage and the terminal voltage is less than the precharge threshold for the threshold amount of time (YES), method 400 proceeds to 414 and includes closing the main relay. Closing the main relay may create a conductive path to electrically couple the battery pack and the device without going through the precharge relay. In this way, precharging is finished and method 400 ends.

If at 412, method 400 determines that the absolute value of the difference of the stack voltage and terminal voltage is not less than the precharge threshold for the threshold amount of time (NO), method 400 proceeds to 416 and determines if the precharge time is elapsed. The method may determine if the precharge time is elapsed by determining a time elapsed since the precharge relay was closed at step 404. The precharge time may be the time determined during the precharge bus check as described above with respect to method 300 and stored on non-volatile memory of the controller. Determining if the precharge time is elapsed may include comparing the stored precharge time to the time elapsed since the precharge relay at step is closed 404 and determining if the time elapsed is greater than, equal to or less than the stored precharge time. If the precharge time is not elapsed (NO) (e.g., the stored precharge time is greater than the time elapsed), method 400 returns to 411. In this way, the method has learned the expected time for precharging and does not continue on to retry the precharge until that expected time is elapsed.

If at 416, method 400 determines that the precharge time is elapsed (YES) (e.g., the stored precharge times is less than or equal to the elapsed time), method 400 proceeds to 418 and includes opening the precharge relay and setting the circuit breaker (CB) status to precharge retry and incrementing the precharge counter. As discussed above, the circuit breaker status may be read by the controller of the device. Method 400 also proceeds to 418 if at 410 the method determines that the protection score is equal to one. A protection score equal to the maximum value indicates that overcurrent and/or short circuit conditions may be present.

At 420, method 400 includes measuring battery pack current calculating the recovery time and protection score. Measuring the battery pack current and calculating the recovery time and protection score may be the same as steps 406 and 408. In this way the protection score stored in the non-volatile memory of the controller may be updated from the values stored at steps 406 and 408 and replaced with new values.

At 422, method 400 determines if the protection score is equal to zero. If method 400 determines the protection score is not zero (NO), method 400 returns to 420 and again measures the battery pack current and calculates the recovery time and protection score. If at 422, method 400 determines that the protection score is equal to zero, method 400 returns to 404 and again closes the precharge relay and sets the CB status to precharge pending. In this way, the amount of wait time between precharge attempts is dynamically adjusted based on the conditions of the precharge circuit.

Turning now to FIG. 5, an alternate example of a method 500 for precharging using a precharging circuit while monitoring and preventing short circuit and overcurrent conditions is shown. Method 500 may occur after a precharge time is successfully determined and the device is ready to electrically couple to the battery pack, as described above with respect to FIG. 3.

At 502, method 500 includes closing the precharge relay. For example, closing precharge relay 206 of FIG. 2. In this way, the precharge process starts and current may flow through a resistor (e.g., resistor 210 of FIG. 2) of the battery pack. At 504, method 500 includes starting the precharge timer and setting the circuit breaker status to precharge pending. The precharge timer may be stored in non-volatile memory of the controller and may track a time elapsed since closing the precharge relay at 502. The circuit breaker status may be stored in non-volatile memory of the controller and referred to by the controller of the battery pack or controller of the device as discussed above.

At 505, method 500 includes measuring a current and temperature of the battery pack. The current and temperature of the battery pack may be measured by respective sensors of the battery pack communicatively coupled to the controller. The measured current may include the current flowing from the plurality of battery cells through the precharge relay to the terminals.

At 506, method 500 determines if the battery temperature is less than a precharge threshold temperature. The precharge threshold temperature may be a temperature above which battery pack components may degrade if current is flowing. As one example, the precharge threshold temperature may be 150° C. The temperature may be determined using a temperature sensor included in the battery pack (e.g., one of sensors 112) communicatively coupled to the controller and compared to the threshold temperature.

If at 506 at method 500 determines that the temperature is not less than the precharge threshold temperature (NO), method 500 proceeds to 507 and includes opening the precharge relay, outputting a precharge error, and resetting the precharge timer. Resetting the precharge timer may include setting the precharge timer to zero in preparation of retrying precharging. Outputting the precharge error may include providing an indication to the user that the precharge is failed. For example, the battery pack may emit a sound or light to indicate the error. In some examples, outputting the precharge error may include outputting the error from the controller to a controller of the device coupled to the battery pack. The device may indicate, for example through a sound, light, or a display, that the precharge was not successful. Outputting the precharge error may also include updating the circuit breaker status to precharge error. Method 500 ends.

If at 506 at method 500 determines that the temperature is less than the precharge threshold temperature (YES), method 500 proceeds to 508 and includes determining if the absolute value of the battery pack current is less than a resistor threshold current. The battery pack current may be determined by a current sensor of the battery pack communicatively coupled to the controller. The resistor threshold current may be current which the resistor may withstand without degrading for 1 s. The controller may compare the absolute value of the measured battery pack current to the resistor threshold current. In one example the resistor threshold current may be 10 A.

If at 508, method 500 determines that the absolute value of the measured battery pack current is less than the resistor threshold current (YES), method 500 proceeds to 510 and includes decrementing the precharge accumulator by a decrement amount. The precharge accumulator may be a variable stored in the non-volatile memory of the controller and may be used to track energy accumulated by the precharge circuit during precharging. Decrementing may include subtracting a decrement amount from the stored precharge accumulator value. The decrement amount may be an energy which is based on a time of one current measurement loop and an energy threshold. As one example, the decrement amount may be 0.75 J.

At 511, method 500 measures a stack voltage and terminal voltage of the battery pack. The stack voltage may be measured by a stack voltage sensor and the terminal voltage may be measured by a terminal voltage sensor as discussed above with respect to methods 400 and 300.

At 512, method 500 determines if the absolute value of the stack voltage and terminal voltage difference is less than a threshold amount for a threshold amount of time. Step 512 may be the same as step 412 of method 400. Determining if the absolute value of the difference between stack voltage and terminal voltage difference is less than a threshold amount for a threshold amount of time may determine if the precharging circuit has successfully equalized the voltages at the terminal and across the plurality of battery cells.

If method 500 determines YES at 512, method 500 proceeds to 514 and includes closing the main relay and resetting the precharge timer. Resetting the precharge timer may include setting the precharge time back to a zero value to be ready for the next time the precharge circuit is activated. In this way, the precharge is finished and the battery pack is coupled to the device through the main relay. Method 500 ends.

If method 500 determines NO at 512, method 500 proceeds to 516 and determines if the precharge time is elapsed. The method may determine if the precharge time is elapsed by comparing the value accumulated in the precharge timer started at 504 with the precharge time stored in the non-volatile memory of the controller in step 310 of method 300. If method 500 determines that the precharge time is elapsed (YES), method 500 proceeds to 507 and opening the relay, resetting the precharge timer and outputting an error message. If at 516, method 500 determines that the precharge time has not elapsed (NO), method 500 returns to 505 and again measures the battery pack current and temperature and then determines if the battery temperature is less than the precharge threshold temperature. In this way, method 500 then continues to monitor the precharge circuit until the known precharge time has elapsed, after which an error may be output.

Returning now to step 508, if method 500 determines that the absolute value of pack current is not less than the resistor threshold (NO), method 500 proceeds to 518 and includes calculating an increment amount and incrementing the precharge accumulator by the increment amount. The increment amount may be calculated in the same way as the increment amount is calculated for the precharge check accumulate described above with respect to step 316, as specified by equation 1. Incrementing may include adding the increment amount to the stored precharge accumulator to increase the precharge accumulator by the increment amount.

At 520, method 500 determines if the precharge accumulator is greater than the energy threshold. The energy threshold may be an amount of energy, above which components of the precharge circuit are likely to degrade. The energy threshold may be based on an amount of current tolerated by the resistor in a certain time window. In some examples, the energy threshold may be the same as the energy threshold compared to the precharge check accumulator at step 318 of method 300. As one example, the energy threshold may be 75 joules.

If method 500 determines that the precharge accumulator is greater than the energy threshold (YES) at 520, method 500 proceeds to 507 and includes opening the precharge relay, outputting the precharge error and resetting the precharge timer. Method 500 ends.

If at 520, method 500 determines that the precharge accumulator is not greater than the energy threshold (NO), method 500 returns to 511 and again measures the stack voltage and terminal voltage and determines if the absolute value of the stack voltage and terminal voltage different is less than the precharge threshold for the threshold amount of time. In this way, method 500 may monitor for accumulated energy of the precharge circuit during a learned precharge time in order to open the precharge relay and output an error message if the system shows any signs of a short circuit or overcharge condition such as the precharge taking too long or the system accumulating too much energy and/or heat before the precharge is complete.

Turning now to FIG. 6, diagrams 600, 604, and 606 are shown of repeated precharge events over time. The x-axis of diagrams 600, 604, and 606 is time and the y-axis indicates accumulated energy of the precharge circuit. X markers 601 along the x-axis indicate a failed precharge event. For example, a failed precharge event may include stopping the precharge timer and opening the precharge relay, opening the precharge relay, setting a circuit breaker status to precharge retry and incrementing a precharge counter, and/or opening the precharge relay, outputting a precharge error and resetting a precharge timer. A precharge event may include closing of the precharge relay of the precharge circuit. The precharge event may reoccur if a previous precharge event is not successful (e.g., the precharge relay is opened and an error message is output).

First diagram 600 corresponds to multiple precharge attempts following the methods of FIGS. 3, 4, and 5 of the subject application. Energy as denoted by filled plot 610 may be accumulated in the precharge circuit as a result of failed precharge attempts. A dynamically timed re-try event 602 may occur at the time when energy is dissipated from the precharge circuit.

In contrast to the dynamically timed re-try event 602, diagrams 604 and 606 correspond to re-try events occurring after a set, static, elapsed amount of time after the failed precharge event. As shown in diagram 604, the static elapsed amount of time may be too long. In such an example, there is an elapsed amount of time between when the accumulated energy is dissipated the delayed re-try event 605. The delayed re-try event may be frustrating for a consumer attempting to start the device. As shown in diagram 606, the static elapsed amount of time may also be too short. In such examples, premature re-try event 608 may occur before the energy is dissipated. Premature re-trying may contribute to degradation of the precharge circuit.

The technical effect of methods 300, 400, and 500 is to dynamically learn an expected precharge time for a precharge circuit and then use the precharge time to determine if a short circuit and/or overcurrent conditions are occurring during precharging. The methods account for both energy accumulated and dissipated by the precharging circuit during precharging to determine if a precharge relay demands opening and an error message is output. In this way, the precharging may be stopped when it is dynamically determined to be demanded to prevent degradation of the components, not prematurely or too late to prevent degradation. Further, as illustrated in FIG. 6, retrying a precharge event may also use a wait a time that is dynamically determined by the method to not wait overly long and inconvenience the user, or to be overly short as to cause component degradation.

The disclosure also provides support for a method for a precharge circuit of a battery pack, comprising: closing a precharge relay of the precharge circuit, storing a precharge time in non-volatile memory of a controller of the battery pack if an absolute value of a difference between a stack voltage and a terminal voltage is less than a precharge threshold and outputting an error message if the difference is not less than the precharge threshold and a value of a precharge check accumulator is greater than an energy threshold, opening the precharge relay, if the precharge time is stored, closing the precharge relay, and precharging and monitoring for short circuit and/or overcurrent conditions using the stored precharge time. In a first example of the method, the method further comprises: incrementing the value of the precharge check accumulator if the difference is not less than the precharge threshold. In a second example of the method, optionally including the first example, the incrementing includes adding an increment based on a measured current of the battery pack, a resistance of a resistor of the precharge circuit, and a time constant of the method. In a third example of the method, optionally including one or both of the first and second examples, the energy threshold depends on a current withstood by a resistor of the precharge circuit over time. In a fourth example of the method, optionally including one or more or each of the first through third examples, the error message indicates the precharge circuit is on a bus not configured for the precharge circuit.

The disclosure also provides support for a battery pack, comprising: a precharge circuit including a precharge relay, a resistor, and main relay, a terminal voltage sensor, a stack voltage sensor, and a current sensor, each electrically coupled to the precharge circuit, and a controller communicatively coupled to the precharge circuit, the terminal voltage sensor, the stack voltage sensor and the current sensor, and including a non-volatile memory storing instructions that when executed cause the controller to: close the precharge relay, measure a battery pack current, calculate a recovery time and protection score of the precharge relay, in response to the protection score not equal to 1 and an absolute value of a difference in voltage between a stack voltage and a terminal voltage less than a precharge threshold, close the main relay, and in response to the protection score equal to 1 or the absolute value of the difference in voltage between the stack voltage and terminal voltage greater than the precharge threshold after a precharge time elapsed, open the precharge relay. In a first example of the system, the recovery time is based on a maximum rated power of the precharge relay at the measured battery pack current. In a second example of the system, optionally including the first example, the protection score is based on a maximum rated power of the precharge relay and the recovery time. In a third example of the system, optionally including one or both of the first and second examples, the protection score is based on a ratio of effective power to maximum rated power of the precharge relay and on ratio of a time interval to the recovery time. In a fourth example of the system, optionally including one or more or each of the first through third examples, the precharge time is determined by the controller for the precharge circuit before the controller closes the precharge relay. In a fifth example of the system, optionally including one or more or each of the first through fourth examples, the instructions further include to close the precharge relay after the precharge relay is opened in response to the protection score being equal to zero. In a sixth example of the system, optionally including one or more or each of the first through fifth examples, the controller stores a precharge counter. In a seventh example of the system, optionally including one or more or each of the first through sixth examples, the instructions include to increase the precharge counter by one after the controller determines the protection score is equal to one and opens the precharge relay.

The disclosure also provides support for a battery pack, comprising: a precharge circuit including a precharge relay, a resistor, and main relay, a terminal voltage sensor, a stack voltage sensor, and a current sensor, each electrically coupled to the precharge circuit, and a controller communicatively coupled to the precharge circuit, the terminal voltage sensor, the stack voltage sensor and the current sensor, and including a non-volatile memory storing instructions that when executed cause the controller to: close the precharge relay, increment or decrement a precharge accumulator in response to comparing an absolute value of a measured battery pack current to a resistor threshold, and in response to the precharge accumulator being above an energy threshold or an absolute value of a difference in voltage between a stack voltage and a terminal voltage greater than a precharge threshold, open the precharge relay. In a first example of the system, the battery pack includes a temperature sensor communicatively coupled to the controller and the instructions include to open the precharge relay if a temperature is greater than a precharge threshold temperature. In a second example of the system, optionally including the first example, the instructions include to increment the precharge accumulator if the absolute value of the measured battery pack current is greater than the resistor threshold. In a third example of the system, optionally including one or both of the first and second examples, the increment is based on a measured current of the battery pack, a resistance of the resistor of the precharge circuit, and a time constant. In a fourth example of the system, optionally including one or more or each of the first through third examples, the instructions include to decrement the precharge accumulator if the absolute value of the measured battery pack current is less than the resistor threshold. In a fifth example of the system, optionally including one or more or each of the first through fourth examples, the energy threshold depends on a current withstood by the resistor of the precharge circuit over time. In a sixth example of the system, optionally including one or more or each of the first through fifth examples, the instructions include to close the main relay in response to the absolute value of the difference in voltage between the stack voltage and the terminal voltage less than the precharge threshold for a threshold amount of time.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A method for a precharge circuit of a battery pack, comprising:
closing a precharge relay of the precharge circuit;
storing a precharge time in non-volatile memory of a controller of the battery pack if an absolute value of a difference between a stack voltage and a terminal voltage is less than a precharge threshold and outputting an error message if the difference is not less than the precharge threshold and a value of a precharge check accumulator is greater than an energy threshold;
opening the precharge relay;
if the precharge time is stored, closing the precharge relay; and
precharging and monitoring for short circuit and/or overcurrent conditions using the stored precharge time.

2. The method of claim 1, further comprising incrementing the value of the precharge check accumulator if the difference is not less than the precharge threshold.

3. The method of claim 2, wherein the incrementing includes adding an increment based on a measured current of the battery pack, a resistance of a resistor of the precharge circuit, and a time constant of the method.

4. The method of claim 1, wherein the energy threshold depends on a current withstood by a resistor of the precharge circuit over time.

5. The method of claim 1, wherein the error message indicates the precharge circuit is on a bus not configured for the precharge circuit.

6. A battery pack, comprising:
a precharge circuit including a precharge relay, a resistor, and a main relay;
a terminal voltage sensor, a stack voltage sensor, and a current sensor, each electrically coupled to the precharge circuit; and
a controller communicatively coupled to the precharge circuit, the terminal voltage sensor, the stack voltage sensor and the current sensor, and including a non-volatile memory storing instructions that when executed cause the controller to:
close the precharge relay;
measure a battery pack current via the current sensor;
calculate a recovery time and protection score of the precharge relay;
in response to the protection score not equal to a maximum value and an absolute value of a difference in voltage between a stack voltage and a terminal voltage less than a precharge threshold, close the main relay; and
in response to the protection score equal to the maximum value or the absolute value of the difference in voltage between the stack voltage and terminal voltage greater than the precharge threshold after a precharge time elapsed; open the precharge relay.

7. The battery pack of claim 6, where the recovery time is based on a maximum rated power of the precharge relay at the measured battery pack current.

8. The battery pack of claim 6, wherein the protection score is based on a maximum rated power of the precharge relay and the recovery time.

9. The battery pack of claim 6, wherein the protection score is based on a ratio of effective power to maximum rated power of the precharge relay and on a ratio of a time interval to the recovery time.

10. The battery pack of claim 6, wherein the precharge time is determined by the controller for the precharge circuit before the controller closes the precharge relay.

11. The battery pack of claim 6, wherein the instructions further include to close the precharge relay after the precharge relay is opened in response to the protection score being equal to zero.

12. The battery pack of claim 6, wherein the controller stores a precharge counter.

13. The battery pack of claim 12, wherein the instructions include to increase the precharge counter by one after the controller determines the protection score is equal to one and opens the precharge relay.

14. A battery pack, comprising:
a precharge circuit including a precharge relay, a resistor, and main relay;
a terminal voltage sensor, a stack voltage sensor, and a current sensor, each electrically coupled to the precharge circuit; and
a controller communicatively coupled to the precharge circuit, the terminal voltage sensor, the stack voltage sensor and the current sensor, and including a non-volatile memory storing instructions that when executed cause the controller to:
close the precharge relay;
increment or decrement a precharge accumulator in response to comparing an absolute value of a measured battery pack current to a resistor threshold; and
in response to the precharge accumulator being above an energy threshold or an absolute value of a difference in voltage between a stack voltage and a terminal voltage greater than a precharge threshold, open the precharge relay.

15. The battery pack of claim 14, wherein the battery pack includes a temperature sensor communicatively coupled to the controller and the instructions include to open the precharge relay if a temperature is greater than a precharge threshold temperature.

16. The battery pack of claim 14, wherein the instructions include to increment the precharge accumulator if the absolute value of the measured battery pack current is greater than the resistor threshold.

17. The battery pack of claim 16, wherein the increment is based on a measured current of the battery pack, a resistance of the resistor of the precharge circuit, and a time constant.

18. The battery pack of claim 14, wherein the instructions include to decrement the precharge accumulator if the absolute value of the measured battery pack current is less than the resistor threshold.

19. The battery pack of claim 14, wherein the energy threshold depends on a current withstood by the resistor of the precharge circuit over time.

20. The battery pack of claim 14, wherein the instructions include to close the main relay in response to the absolute value of the difference in voltage between the stack voltage and the terminal voltage less than the precharge threshold for a threshold amount of time.
